(19) United States
(12) Patent Application Publication
(10) Pub. No.: US 2010/0230821 A1
(43) Pub. Date: Sep. 16, 2010

(54) METHOD OF MANUFACTURING A SEMICONDUCTOR DEVICE AND SEMICONDUCTOR DEVICE OBTAINED WITH SUCH A METHOD

(75) Inventors: Vijayaraghavan Madakasira, Louvain (BE); Lars Magnus Tarle Borgstrom, Eindhoven (NL); Erik Petrus Antonius Maria Bakkers, Eindhoven (NL); Wilhelmus Theodorus Antonius Johan Van Den Einden, Eindhoven (NL); Olaf Wunnicke, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/377,610

(22) PCT Filed: Aug. 13, 2007
(86) PCT No.: PCT/IB07/53211

§ 371 Date: Feb. 16, 2009

(30) Foreign Application Priority Data
Aug. 16, 2006 (EP) 06118967.6

(51) Int. Cl. H01L 29/417; H01L 21/331; H01L 21/335; H01L 21/20

(52) U.S. Cl. 257/773; 438/666; 438/478; 977/762; 257/E29.116; 257/E29.114; 257/E21.09; 257/E21.37; 257/E21.4

(57) ABSTRACT

The invention relates to a method of manufacturing a semiconductor device (10) with a semiconductor body (1) which is provided with at least one semiconductor element, wherein on the surface of the semiconductor body (1) a mesa-shaped semiconductor region (2) is formed, a masking layer (3) is deposited over the mesa-shaped semiconductor region (2), a part (3A) of the masking layer (3) is removed that borders a side surface of the mesa-shaped semiconductor region (2) near its top and an electrically conducting connection region (4) is formed on the resulting structure forming a contact for the mesa-shaped semiconductor region (2). According to the invention after removal of said part (3A) of the masking layer (3) but before formation of the electrically conducting connection region (4) the mesa-shaped semiconductor region (2) is widened by an additional semiconductor region (5) at the side surface of the mesa-shaped semiconductor region (2) freed by removal of said part (3A) of the masking layer (3). In this way device (10) having a very low contact resistance are obtainable in a simple manner. Preferably the mesa-shaped semiconductor region (2) is formed a nano-wire by a further epitaxial growth process like VLS. The additional region (5) may be obtained e.g. by MOVPE.

### FIELD OF THE INVENTION

The invention relates to a method of manufacturing a semiconductor device with a substrate and a semiconductor body which is provided with at least one semiconductor element, wherein on the surface of the semiconductor body a mesa-shaped semiconductor region is formed, a masking layer is deposited over the mesa-shaped semiconductor region, a part of the masking layer is removed that borders a side surface of the mesa-shaped semiconductor region near its top and an electrically conducting connection region is formed on the resulting structure forming a contact for the mesa-shaped semiconductor region. The invention also relates to a semiconductor device obtained with such a method.

### BACKGROUND OF THE INVENTION

Such a method is very suitable for making semiconductor devices like ICs (=Integrated Circuit) or other devices such as discrete devices comprising nano-wire elements as the mesa-shaped semiconductor region. Here with a nano wire a body is intended having at least one lateral dimension between 0.5 and 100 nm and more in particular between 1 and 50 nm. Preferably a nano-wire has dimensions in two lateral directions that are in the said ranges. The length of a nano-wire will typically be e.g. in the order of 1-10 μm. It is further noted here that contacting extremely small dimensions in semiconductors is a challenging technique in semiconductor processing. However, although the mesa-shaped semiconductor region is intended to comprise in particular a nano wire, the invention is also applicable to other mesa shaped semiconductor regions that have other dimensions or are formed in other ways than nano-wires usually are. Mesa-shaped of a region means that the region forms a protrusion on the surface of the semiconductor body.

A method as mentioned in the opening paragraph is known from the PCT (=Patent Cooperation Treaty) patent application that has been published under number WO 2005/064664 on July 2005. In this document it is described how a device is made comprising a heterojunction. A nano-wire of e.g. a III-V material is formed on the surface of a substrate of a IV material like silicon. The nano-wire is formed as a gate around transistor device. The drain thereof is formed by the substrate, the nano-wire forming the channel region, which is surrounded by the gate region that is isolated from the nano-wire. The nano-wire is buried in an electrically insulating layer and by means of polishing the upper surface of the nano-wire is made free. Then, an additional part of the insulating layer is removed by selective etching and in this way an upper part of the side surface of the nano-wire near the top is made free. Subsequently a conductive layer is deposited on the resulting structure forming an electrically conductive connection region for the nano-wire.

A drawback of such a method is that it is that it is not always easy to obtain a low-ohmic contact between the nano-wire and the electrical conducting connection region. This holds in particular if the nano-wire comprises other material than silicon, e.g. a III-V material.

### SUMMARY OF THE INVENTION

It is therefore an object of the present invention to avoid the above drawbacks and to provide a method, which is suitable for the manufacturing of semiconductor devices comprising a mesa-shaped semiconductor region like a nano-wire that allows for a very low-ohmic contact between nano-wire and connection region.

To achieve this, a method of the type described in the opening paragraph is characterized in that after removal of said part of the masking layer but before the formation of the electrically conducting connection region the mesa-shaped semiconductor region is widened by an additional semiconductor region at a side surface of the mesa-shaped semiconductor region freed by removal of said part of the masking layer. The invention is based on the following recognitions. Firstly, by widening the mesa-shaped semiconductor region by the additional semiconductor region the contact area between the connection region and said mesa-shaped semiconductor region is increased. Already in this way the contact resistance can be reduced. Furthermore, for the widening of the semiconductor region, i.e. for the additional semiconductor region, another semiconductor material can be selected than that chosen for the mesa-shaped semiconductor region. In this way, by a suitable choice for said material, the contact resistance can be further reduced. Moreover, since the widening is done in an epitaxial process, the process conditions and the type of epitaxial process can be selected to be optimal for the material in the additional region (the widened region) which forms an optimal choice in view of the desired low contact resistance.

In a preferred embodiment of a method according to the invention the mesa-shaped semiconductor region is formed by a further epitaxial growth process. In this way, the method according to the present invention can be optimal for using a nano-wire as the mesa-shaped semiconductor region. Such a nano-wire can be advantageously formed by a so-called VLS (=Vapor Liquid Solid) epitaxial process.

Preferably the epitaxial growth process is performed at a higher temperature than the further epitaxial growth process. The further epitaxial process, in particular the before mentioned VLS process requires relatively moderate temperatures for optimal results. On the other hand, the additional semiconductor region, i.e. the widened region, requires a higher growth temperature in order to obtain the desired freedom in choice for the selection of the semiconductor material for the widened region. Such “high” growth temperature epitaxial process may be VPE (=Vapor Phase Epitaxy), MBE (=Molecular Beam Epitaxy), MOVPE (=Metal Organic Vapor Phase Epitaxy), MOMBE (=Metal Organic Molecular Beam Epitaxy), LPE (=Liquid Phase Epitaxy) or ALE (=Atomic Layer Epitaxy). These processes can function between e.g. 200 and 900, and preferably between e.g. 550 to 700 degrees Celsius whereas the before mentioned VLS process functions in the temperature range of 350 to 450 degrees Celsius. In addition higher temperatures can be used depending on the material grown. For nitride nano-wires a typical growth temperature is in the range from 700-800 degrees Celsius.

In an advantageous modification the epitaxial growth process and the further epitaxial growth process are performed in the same growth apparatus. This is efficient and offers advantages like keeping the device clean. Both growth processes may be used intermittently in order to modify the shape of the additional region. Another possibility is to continue the nano wire growth after the wire has been widened by the additional region. For the latter variation it is not necessary to perform both growth processes in the same equipment.

In a further embodiment the additional semiconductor region is highly doped, preferably higher than the mesa-shaped semiconductor region. This also allows for reduction of (the thickness of) a Schottky barrier and thus also for a low contact resistance. Moreover, the material of the additional region can be selected to allow for a very high doping thereof. Furthermore, such a high doping can be used for doping the nano-wire, or at least the upper part thereof, by means of out diffusion. A RTA (=Rapid Thermal Anneal) process may be used to obtain this result if desired.

Preferably for the additional semiconductor region and the mesa-shaped semiconductor region different semiconductor materials are selected. The advantage thereof has been already explained above. In order to reduce a possible strain in the structure due to lattice mismatch between various materials, grading of the composition may be used. Also the thickness of the additional region can be chosen to be sufficiently low to allow for low strain. If the top of the nano-wire is not available for the epitaxial growth process, the growth can be merely lateral and the thickness of the additional region can be made as low as desired by chosen a very limited height of the part of the nano-wire protruding from the masking layer. If the growth is also allowed on top of the nano-wire, the thickness of the additional region may be reduced by an additional etching step.

In another embodiment for the mesa-shaped semiconductor region a high-bandgap III-V semiconductor material is chosen and for the additional semiconductor region a low-bandgap III-V semiconductor material is chosen. In this way the nano-wire can have optimal properties for functioning as a part of a transistor whereas the additional region is optimal for a low contact resistance.

Preferably the electrically conducting connection region is formed contacting the additional semiconductor region. However, the connection region may also contact the upper surface of the nano-wire. For the masking layer, preferably an insulating layer is chosen. Such layers function very well for obtaining selective epitaxy on semiconductor regions not covered by them. Suitable material may be silicon dioxide or silicon nitride. Preferably the masking layer is provided with a thickness that is much smaller than the height of the mesa-shaped semiconductor region and that on top of the masking layer a photo resist layer is deposited having a thickness that is smaller than but close to the height of the semiconductor region, whereinafter a part of the masking layer not covered by the photo resist layer is removed and subsequently the photo resist layer is removed. Such method is relatively fast and cheap since the process involved are fast and the amount of material used is either small or cheap. Instead of a regular photo resist a PMMA (=Poly Methyl Meta Acrylate) material may be used at this point. The advantage of such a PMMA material is that it covers the structures in a self-planarized manner. A simple and short dry or wet PMMA etch can be used to reduce the thickness of said layer after deposition in order to expose (more of) the nano-wire.

After formation of the additional semiconductor region, preferably a thick isolation region is deposited and the structure is planarized at least at the level below the additional semiconductor region.

As already mentioned before, preferably a nano-wire is chosen for the mesa-shaped semiconductor region. As a starting point for the semiconductor body, preferably a silicon substrate is selected. Formation of a semiconductor body with a silicon substrate allows for integration of other devices or components in standard silicon technology. Silicon is also very suitable for the application of the VLS technique for forming nano-wires.

For the semiconductor element preferably a transistor is chosen. The mesa-shaped semiconductor region (nano-wire) may form the emitter or collector of a bipolar transistor or a contact to a source or drain of a field effect transistor.

Finally, the present invention also comprises a semiconductor device obtained by a method according to the invention.

These and other aspects of the invention will be apparent from and elucidated with reference to the embodiments described hereinafter, to be read in conjunction with the drawings.

### BRIEF DESCRIPTION OF THE DRAWINGS

FIGS. 1 through 8 are sectional views of a semiconductor device at various stages in its manufacture by means of a method in accordance with the invention.

### DETAILED DESCRIPTION OF AN EMBODIMENT

The Figures are diagrammatic and not drawn to scale, the dimensions in the thickness direction being particularly exaggerated for greater clarity. Corresponding parts are generally given the same reference numerals and the same hatching in the various Figures.

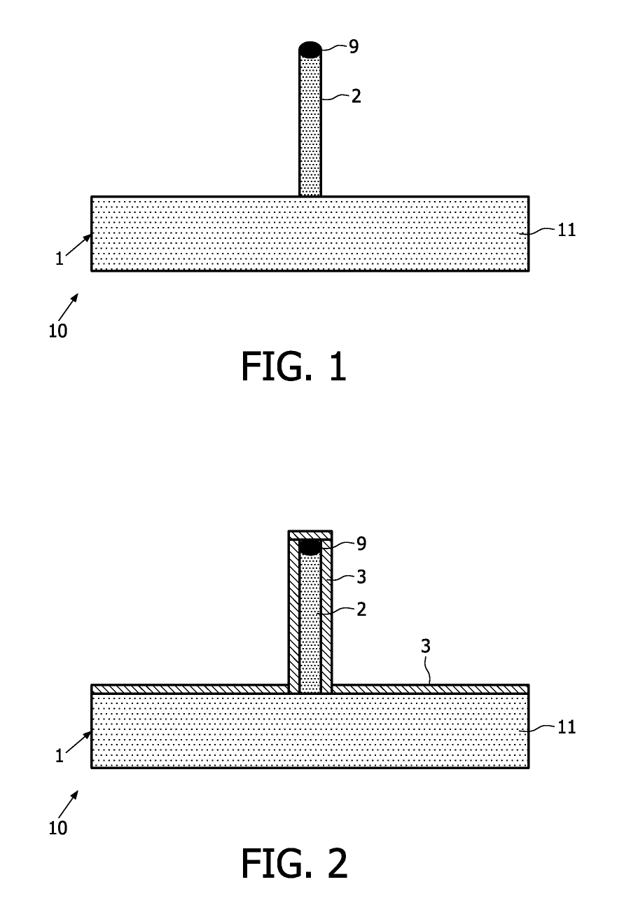

FIGS. 1 through 8 are sectional views of a semiconductor device at various relevant stages in its manufacture by means of a method in accordance with the invention. The semiconductor device to be manufactured may contain already at the stage in advance of FIG. 1 a semiconductor element—or a plurality of such elements—that may have been formed in a usual manner. The element may be e.g. a field effect transistor or a bipolar transistor. The mesa-shaped region that is formed in the method of this example may be e.g. a contact structure for the source/drain region of field effect transistor or the emitter of a bipolar transistor the collector region in an inverted bipolar transistor. The features of such a transistor are for reasons of simplicity not shown in the drawing.

In a first relevant step of the manufacture of the device 10 (see FIG. 1) a silicon substrate 11 forming a silicon semiconductor body 1 in which a semiconductor element, e.g. a field effect or bipolar transistor, has already been (largely) formed, is provided with a mesa-shaped semiconductor region 2, here nano-wire(s) 2 comprising e.g. a high-bandgap III-V material like GaN. These wires 2 can be formed e.g. by photolithography and etching of a uniformly deposited layer but also by a selective deposition technique as described in e.g. “Vapor-liquid-solid mechanism of single crystal growth” by R. S. Wagner and W. C. Ellis that has been published in Applied Physics Letters, vol. 4, no. 5, 1 march 1964, pp 89-90. In this example the height of the pillar 2 is about 500 nm and its diameter is about 50 nm. Region 9 on top of the wire 2 is formed by e.g. a Gold drop used in said VLS growth technique. Please note in this respect that self-catalyzed GaN nano-wires have been presented that are grown without the use of Au as a catalyst.

Subsequently (see FIG. 2) a thin layer 3 of silicon dioxide is deposited using CVD (=Chemical Vapor Deposition) and TEOS (=Tetra Ethyl Ortho Silicate) as source material. In this example the layer 3 is 10 nm thick and its thickness is substantially the same at every location. The function of this layer 3 is to form an anchor and a masking layer for the thin pillar 1 against epitaxial growth in a subsequent epitaxial deposition process.

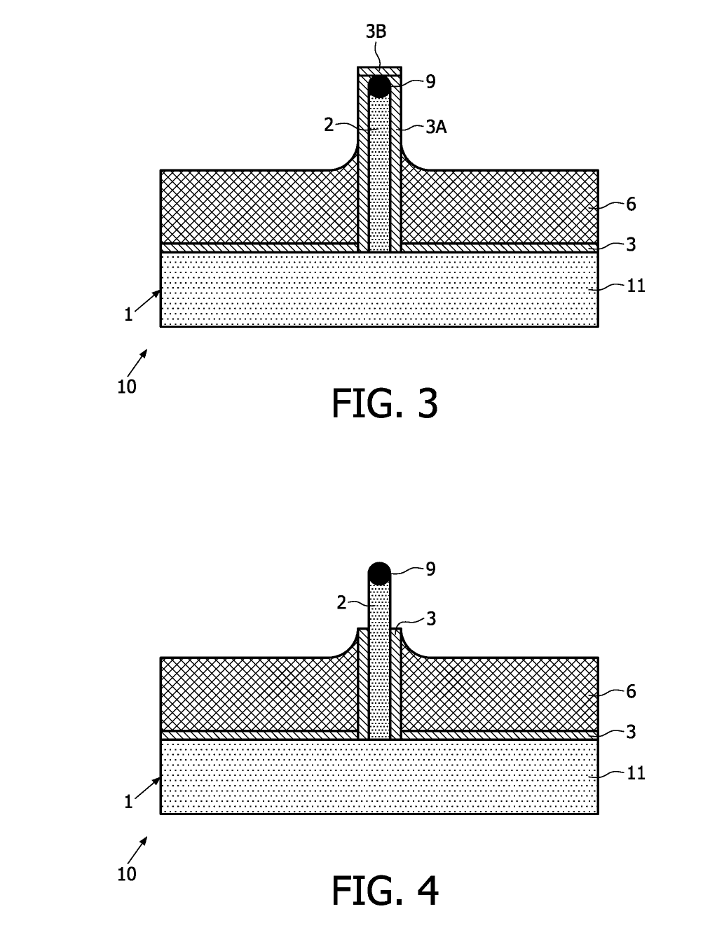

Next (see FIG. 3) a thick photo resist layer 6 is deposited over the structure, e.g. by spinning The thickness of said resist layer 6 is selected to be about 475 nm. Thus a part of the nano-wire 2 which is covered by part 3A of the masking layer 3 protrudes from the resist layer 6 and has a height of about 25 nm (=500 nm−475 nm). As mentioned before a combination of depositing a (PMMA) resist layer 6 followed by etching back said layer may be used to obtain exposure of the nano-wire 2 tip over a desired length near its top. Adjustment of said length may be done in the same manner. In this way, no critical process specification is required with respect to the resist thickness.

Hereinafter (see FIG. 4) part 3A of the insulating layer 3 is removed by selective etching, e.g. by a buffered aqueous HF solution. The etching is done on time base using the known etching rate.

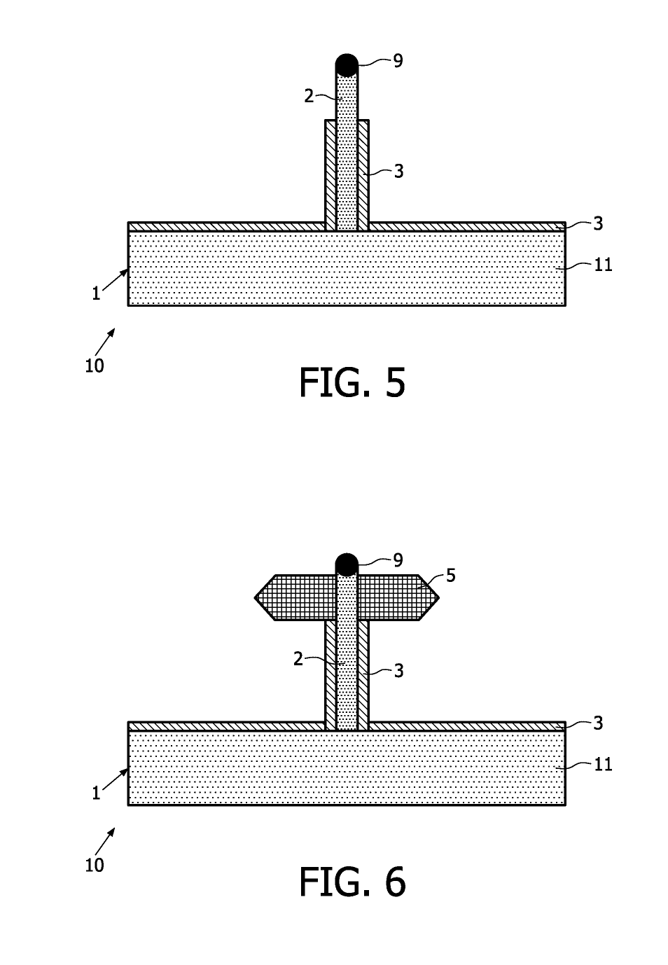

Subsequently (see FIG. 5) the photo resist layer 6 is removed, e.g. by a suitable organic solution. The structure may now be cleaned in various manners and a dip in an aqueous solution of HF may be used to remove any oxide on the surface of the semiconductor region 2 that is free accessible.

The resulting structure (see FIG. 6) is then placed in an epitaxial growth apparatus like an MOVPE apparatus. After heating to a growth temperature e.g. in the range of 550 to 700 degrees Celsius, an additional semiconductor region 5 is grown on the freed side face of the nano-wire 2. In this example, the Gold drop 9 is still present on top of the nano-wire 2 and prevent the epitaxial growth on top of the nano-wire 2 and thus, the epitaxial growth is substantially lateral. Here the additional region 5 is provided with highly doped GaAs or GaInAs. The growth is terminated as soon as the lateral dimension of the additional region 5 is something like e.g. in the range of 100 to 1000 nm.

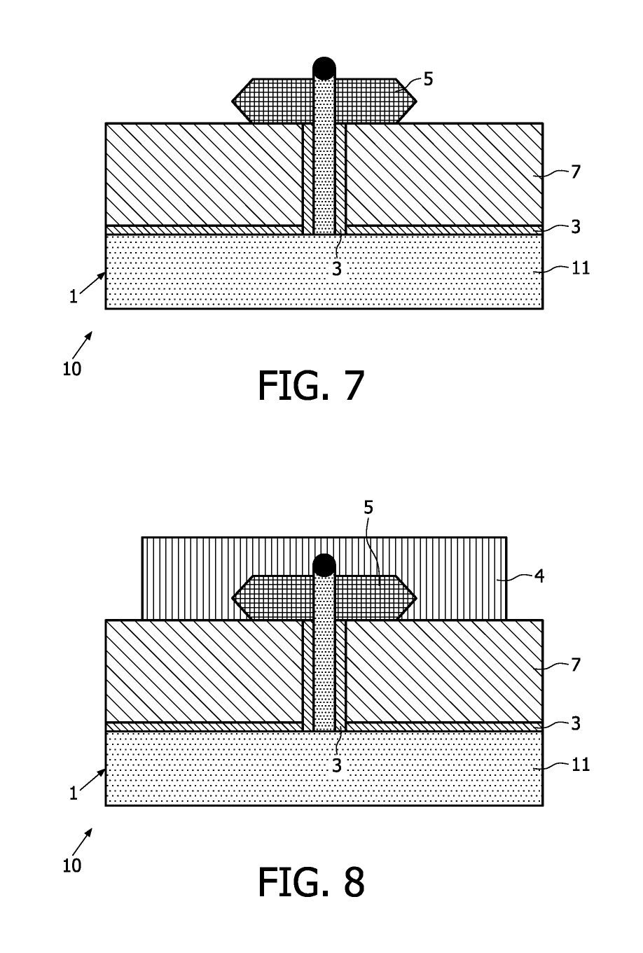

Next (see FIG. 7) the device structure 10 is planarized by deposition of a thick dielectric 7. This may be done e.g. by following the scheme described in European Application number 05110790.2. The dielectric 7 may comprise silicon dioxide.

Now (see FIG. 8) a metal layer, here a titanium-gold double layer having a thickness of e.g. in the range between 0.1 and 1 μm, is deposited over the structure, e.g. using sputtering or a vapor deposition technique. The metal layer can be transformed to connection region 4 by a patterning step like photolithography followed by etching of the metal layer and then the structure may be subjected to a subsequent heating treatment if desired. The resulting structure contains a nano-wire, which is provided with a connection region having a very low-ohmic contact resistance.

Next—the following steps are not shown in the drawing—a PMD (=Pre Metal Dielectric) layer is deposited comprising silicon dioxide having a thickness of e.g. 1000 nm and using CVD. After this step contact holes are formed in the PMD layer using photolithography and etching. Finally a metal layer e.g. of aluminum, is deposited and patterned in order to contact the larger dimension connection region 4. Individual devices 10 that are suitable for mounting are obtained after applying a separation technique like etching or sawing.

It will be obvious that the invention is not limited to the examples described herein, and that within the scope of the invention many variations and modifications are possible to those skilled in the art.

For example it is to be noted that the invention is not only suitable for the manufacture of a discrete device like a transistor but for the manufacture of ICs like (C)MOS or BI(C)MOS ICs but also bipolar ICs. Each nano wire region can for part of a single (part of a) device but it also is possible to use a plurality of nano wires forming a part of a single device or of a single region of a device.

Furthermore it is noted that various modifications are possible with respect to individual steps. For example other deposition techniques can be selected in stead of those used in the example. The same holds for the materials selected. Thus, the (further) insulating layer could be made of e.g. silicon nitride.

Finally it is to be emphasized again that the present invention allows for making a device with a mesa-shaped region with a very small lateral dimension like in the case of a nano wire that on the one hand contains a large doping level while it on the other hand can be provided with a large contacting pad.

1. Method of manufacturing a semiconductor device (10) with a semiconductor body (1) which is provided with at least one semiconductor element, wherein on the surface of the semiconductor body (1) a mesa-shaped semiconductor region (2) is formed, a masking layer (3) is deposited over the mesa-shaped semiconductor region (2), a part (3A) of the masking layer (3) is removed that borders a side surface of the mesa-shaped semiconductor region (2) near its top and an electrically conducting connection region (4) is formed on the resulting structure forming a contact for the mesa-shaped semiconductor region (2), characterized in that after removal of said part (3A) of the masking layer (3) but before formation of the electrically conducting connection region (4) the mesa-shaped semiconductor region (2) is widened by an additional semiconductor region (5) at the side surface of the mesa-shaped semiconductor region (2) freed by removal of said part (3A) of the masking layer (3).

2. Method according to claim 1, characterized in that the mesa-shaped semiconductor region (2) is formed by a further epitaxial growth process.

3. Method according to claim 2, characterized in that the epitaxial growth process is performed at a higher temperature than the further epitaxial growth process.

4. Method according to claim 2, characterized in that the epitaxial growth process and the further epitaxial growth process are performed in the same growth apparatus.

5. Method according to claim 1, characterized in that the additional semiconductor region (5) is highly doped, preferably higher than the mesa-shaped semiconductor region (2).

6. Method according to claim 1, characterized in that for the additional semiconductor region (5) and the mesa-shaped semiconductor region (2) different semiconductor materials are selected.

7. Method according to claim 6, characterized in that for the mesa-shaped semiconductor region (2) a high-bandgap III-V semiconductor material is chosen and for the additional semiconductor region (5) a low-bandgap III-V semiconductor material is chosen.

8. Method according to claim 1, characterized in that the electrically conducting connection region (4) is formed contacting the additional semiconductor region (5).

9. Method according to claim 1, characterized in that for the masking layer (3) an insulating layer is chosen.

10. Method according to claim 1, characterized in that the masking layer (3) is provided with a thickness that is much smaller than the height of the mesa-shaped semiconductor region (2) and that on top of the masking layer (3) a photo resist layer (6) is deposited having a thickness that is smaller than but close to the height of the mesa-shaped semiconductor region (2), whereinafter a part (3A) of the masking layer (3) not covered by the photo resist layer (6) is removed and subsequently the photo resist layer (6) is removed.

11. Method according to claim 1, characterized in that after formation of the additional semiconductor region (5) a thick isolation region (7) is deposited and the structure is planarized at least at the level below the additional semiconductor region (5).

12. Method according to claim 1, characterized in that for the mesa-shaped semiconductor region (2) a nano-wire is chosen.

13. Method according to claim 1, characterized in that as a starting point for the semiconductor body (1) a silicon substrate (11) is selected.

14. Method according to claim 1, characterized in that for the semiconductor element a transistor is chosen.

15. Method according to claim 14, characterized in that the mesa-shaped semiconductor region (2) forms the emitter or collector of a bipolar transistor or forms a contact to a source or drain of a field effect transistor.

16. Semiconductor device (10) obtained by a method according to claim 1.
